(19) United States
(12) Patent Application Publication
(10) Pub. No.: US 2006/0154465 A1
(43) Pub. Date: Jul. 13, 2006

(54) Method for fabricating interconnection line in semiconductor device

(75) Inventors: Bong-seok Suh, Hwaseong-si (KR); Sun-jung Lee, Seoul (KR); Hong-jae Shin, Seoul (KR); Soo-geun Lee, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/330,581

(22) Filed: Jan. 12, 2006

Related U.S. Application Data
(60) Provisional application No. 60/643,730, filed on Jan. 13, 2005.

(30) Foreign Application Priority Data
Apr. 26, 2005 (KR) 10-2005-0034650

(51) Int. Cl. H01L 21/44; H01L 21/4763

(52) U.S. Cl. 438/597; 438/618

(57) ABSTRACT

Provided is a method for fabricating an interconnection line in a semiconductor device. The method includes forming a dielectric layer pattern including a region for forming the interconnection line on a semiconductor substrate, forming a diffusion barrier layer on the dielectric layer pattern, forming a first adhesion layer on the diffusion barrier layer, forming a seed layer on the first adhesion layer, forming a conductive layer to fill the region for forming the interconnection line, performing grain growth of the conductive layer by performing a first annealing process, planarizing the conductive layer to expose the top surface of the dielectric layer pattern, and forming an interface layer through reaction between the first adhesion layer and the conductive layer by performing a second annealing process at a temperature higher than that of the first annealing process.

### BACKGROUND OF THE INVENTION

This application claims priorities from Korean Patent Application No. 10-2005-0034650 filed on Apr. 26, 2005 in the Korean Intellectual Property Office, and U.S. Provisional Patent Application No. 60/643,730 filed on Jan. 13, 2005 in the United States Patent and Trademark Office, the contents of which are incorporated herein in their entireties by reference.

1. Field of the Invention

The present invention relates to a method of fabricating interconnection lines in a semiconductor device, and more particularly, to a method of fabricating interconnection lines in a semiconductor device having enhanced reliability.

2. Description of the Related Art

As the integration of semiconductor devices increases, there is increasing demand for reliable interconnection lines. Copper (Cu) used for an interconnection line of a semiconductor device has a relatively high fusion point, so that it shows superior electro-migration (EM), stress migration (SM), and the like, compared to aluminum (Al). In addition, Cu has low resistivity.

Also, Cu exhibits poor adhesion with respect to an insulating layer such as SiO₂ or SiN or other metals. In addition, in a case of forming a Cu interconnection line using a dual damascene process, a dual damascene interconnection is fabricated by simultaneously forming an upper interconnection layer and a via or a contact plug. Considerable stress induced voids (SIV) may be created at lower portions of dual damascene interconnections due to thermal stress applied to the dual damascene interconnections during heat treatment performed in the course of various manufacturing steps of semiconductor devices. To overcome this problem, that is, to improve adhesiveness between a Cu interconnection line and an insulating layer, an adhesion layer made of Ti, for example, is formed therebetween, followed by forming a Ti—Cu interface layer through a high-temperature annealing process.

However, the inter-diffusion of Ti during the high-temperature thermal process may increase the resistivity of a Cu interconnection line, causing an increase in a resistance-capacitance (RC) time delay.

### SUMMARY OF THE INVENTION

The present invention provides a method for fabricating an interconnection line of a semiconductor device, resulting in improved reliability of the semiconductor device.

According to an aspect of the present invention, there is provided a method for fabricating an interconnection line in a semiconductor device. The method includes forming on a semiconductor substrate a dielectric layer pattern including a region for forming the interconnection line, forming a diffusion barrier layer on the dielectric layer pattern, forming a first adhesion layer on the diffusion barrier layer, forming a seed layer on the first adhesion layer, forming a conductive layer to fill the region for forming the interconnection line, performing grain growth of the conductive layer by performing a first annealing process, planarizing the conductive layer to expose the top surface of the dielectric layer pattern, and forming an interface layer through reaction between the first adhesion layer and the conductive layer by performing a second annealing process at a temperature higher than that of the first annealing process.

In one embodiment, the first annealing process is performed at a temperature where the first adhesion layer and the conductive layer do not react with each other. In one particular embodiment, the first annealing process is performed at a temperature of 300° C. or lower

In one embodiment, the second annealing process is performed at a temperature in a range of 300-600° C.

In one embodiment, the first adhesion layer is formed to a thickness in a range of 10-500 Å.

In one embodiment, the first adhesion layer comprises at least one of Ti, Zr, Hf, Sn, La, and an alloy thereof.

In one embodiment, the conductive layer is formed of at least one of Cu and an alloy thereof.

In one embodiment, the method further comprises, before forming the interface layer, forming on the planar conductive layer a capping layer that protects the planar conductive layer.

In one embodiment, the method further comprises, after forming the interface layer, forming on the planar conductive layer a capping layer that protects the planar conductive layer.

In one embodiment, the method further comprises forming a second adhesion layer on the dielectric layer pattern before forming the diffusion barrier layer.

According to another aspect of the present invention, there is provided a method for fabricating an interconnection line in a semiconductor device, the method including forming on a semiconductor substrate a dielectric layer pattern including a region for forming the interconnection line, forming a diffusion barrier layer on the dielectric layer pattern, forming a seed layer where an adhesive material and a conductive material are combined on the diffusion barrier layer, forming a conductive layer to fill the region for forming the interconnection line, performing grain growth of the conductive layer by performing a first annealing process, planarizing the conductive layer to expose the top surface of the dielectric layer pattern, and forming an interface layer through reaction between the diffusion barrier layer and the conductive layer by performing a second annealing process at a temperature higher than that of the first annealing process.

In one embodiment, the first annealing process is performed at a temperature of 300° C. or lower

In one embodiment, the second annealing process is performed at a temperature in a range of 300-600° C.

In one embodiment, the seed layer is formed to a thickness in a range of 10-500 Å.

In one embodiment, the seed layer contains an adhesive material in an amount not greater than 10% based on the total weight of the mixture.

In one embodiment, the adhesive material is formed of a material selected from the group consisting of Ti, Zr, Hf, Sn, La, and an alloy thereof.

In one embodiment, the conductive layer comprises at least one of Cu and an alloy thereof.

In one embodiment, the method further comprises, before forming the interface layer, forming on the planar conductive layer a capping layer that protects the planar conductive layer.

In one embodiment, the method further comprises, after forming the interface layer, forming on the planar conductive layer a capping layer that protects the planar conductive layer.

In one embodiment, the method further comprises forming an adhesion layer on the dielectric layer pattern before forming the diffusion barrier layer.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a flowchart illustrating a method for fabricating an interconnection line in a semiconductor device according to an embodiment of the present invention.

FIGS. 2A through 8 are sectional views illustrating a method for fabricating an interconnection line in a semiconductor device according to an embodiment of the present invention.

FIGS. 9A and 9B show changes in the concentration depending on positions relative to interconnection lines of a conventional semiconductor device and a semiconductor device according to an embodiment of the present invention.

FIG. 10 is a flowchart illustrating a method for fabricating an interconnection line in a semiconductor device according to another embodiment of the present invention.

FIG. 11 is a flowchart illustrating a method for fabricating an interconnection line in a semiconductor device according to still another embodiment of the present invention.

FIG. 12 is a sectional view illustrating an interconnection line of a semiconductor device according to another embodiment of the present invention.

FIG. 13 is a flowchart illustrating a method for fabricating an interconnection line in a semiconductor device according to yet another embodiment of the present invention.

FIG. 14 is a graphical representation showing the sheet resistance variation of a Cu interconnection line according to positions in an interconnection line of a semiconductor device fabricated according to an embodiment of the present invention.

FIG. 15 is a graphical representation showing the sheet resistance distribution of a Cu interconnection line according to positions in an interconnection line of a semiconductor device fabricated according to an embodiment of the present invention.

### DETAILED DESCRIPTION OF PREFERRED EMBODIMENTS OF THE INVENTION

The present invention will now be described more fully with reference to the accompanying drawings, in which preferred embodiments of this invention are shown. It should be noted that, throughout the description, unless noted otherwise, when a layer is described as being formed on another layer or on a substrate, the layer may be formed directly on the other layer or on the substrate, or one or more layers may be interposed between the layer and the other layer or the substrate.

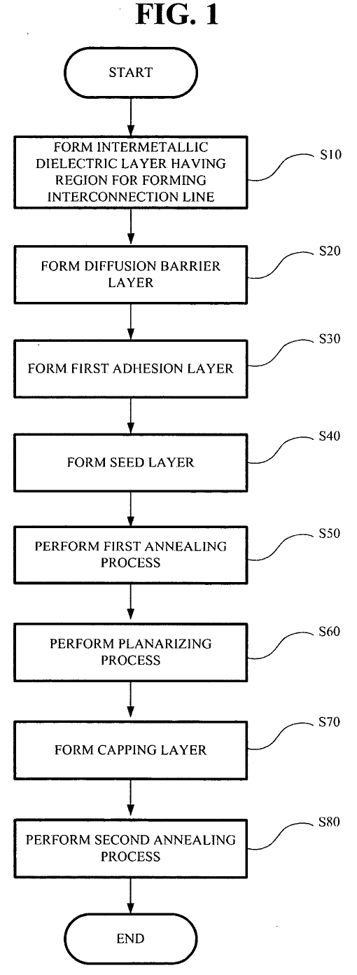

Hereinafter, a method for fabricating an interconnection line in a semiconductor device according to an embodiment of the present invention will be described with reference to FIGS. 1 through 8.

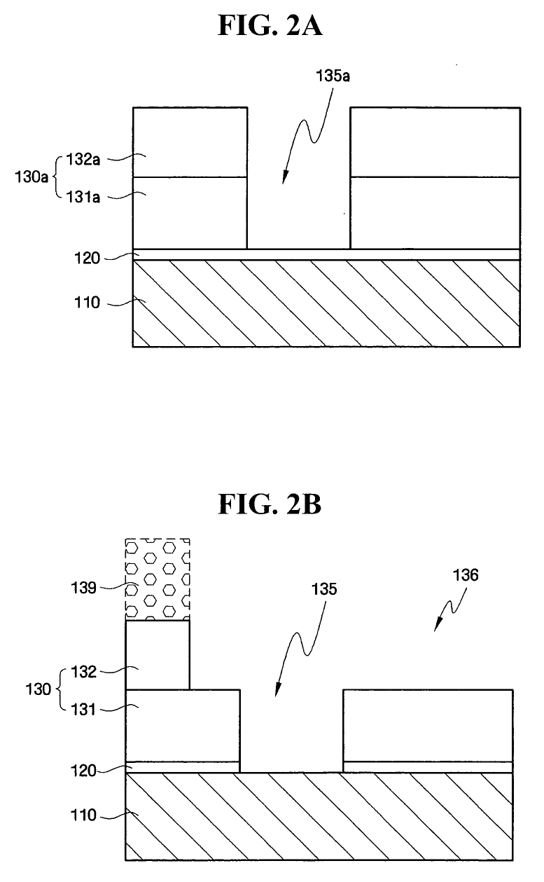

FIG. 1 is a flowchart illustrating a method for fabricating an interconnection line in a semiconductor device according to an embodiment of the present invention, and FIGS. 2A through 8 are sectional views illustrating a method for fabricating an interconnection line in a semiconductor device according to an embodiment of the present invention. It is noted that the interconnection fabrication method described with reference to the dual damascene process can also be applied to a damascene process

Referring to FIGS. 1, 2A, and 2B, an intermetallic dielectric layer pattern 130 having a region for forming an interconnection line is formed on a lower interconnection line layer 110 in step S11. Here, the region for forming an interconnection line is a dual damascene interconnection line region.

Referring to FIG. 2A, a barrier insulating film 120 and intermetallic dielectric (IMD) layer 130a are sequentially deposited on the lower interconnection line layer 110. Next, the barrier insulating film 120 is exposed by performing an etching process on a predetermined region of the IMD layer 130a. As a result, a preliminary via hole 135a is formed.

Here, the barrier insulating film 120 prevents diffusion of Cu during a subsequent thermal process. In addition, the barrier insulating film 120 may serve as an etching stopper during an etching process. That is, the barrier insulating film 120 is used to prevent the lower interconnection line layer 110 from being damaged when forming an interconnection forming trench and/or a via hole by etching the IMD layer 130a or to increase accuracy of etching. The barrier insulating film 120 is preferably formed to a thickness of 200 to 1000 Å, preferably 300 to 700 Å. In addition, the barrier insulating film 120 is preferably formed of SiN, SiC, SiON, or SiCN. The barrier insulating film 120 is formed using a chemical vapor deposition (CVD) technology.

The IMD layer 130a may be formed of a silicon oxide layer (SiO_{X}), a PE-TEOS (plasma enhanced-tetra ethyl ortho silicate), PE-OX (plasma enhanced-oxide), FSG (fluorine doped silicate glass), PSG (phosphorous silicate glass), BPSG (boro phosphorous silicate glass), or USG (undoped silicate glass), and/or may be formed by stacking the above layers. Although a dual-layered structure in which a dielectric layer 131a that is not doped with fluorine (F) and a dielectric layer 132a doped with F, e.g., SiO₂ and FSG are sequentially deposited, is used in an embodiment of the present invention as shown in FIG. 2, the present invention is not limited thereto. That is, the IMD layer 130a may be formed by sequentially depositing a dielectric layer doped with F and a dielectric layer that is not doped with F or may be formed of only a dielectric layer that is not doped with F. Since the dielectric constant of the IMD layer 130a can be reduced by F doping, the overall dielectric constant of an interconnection line in a semiconductor device can be reduced and a resistance-capacitance (RC) time delay can be improved. The IMD layer 130a is preferably formed to a thickness of 5000 to 20000 Å, and typically using a CVD technology.

Referring to FIG. 2B, a photoresist pattern 139 for patterning a trench 136 passing through the preliminary via hole (see 135a of FIG. 2A) is formed. A predetermined region of the IMD layer 130a is etched to a thickness of 2000-10000 Å using the photoresist pattern 139 as a mask, thereby forming the trench 136 passing through the preliminary via hole 135a. The etching method may be, for example, reactive ion etching (RIE). Although a bottom surface of the preliminary via hole 135a may be exposed while the etching process is performed, the barrier insulating film (see 120 of FIG. 2A) partially remains on the bottom surface of the preliminary via hole 135a due to high etching selectivity between the IMD layer 130a and the barrier insulating film 120.

Next, the photoresist pattern 139 is removed and then the barrier insulating film 120 remaining on the bottom surface of the preliminary via hole 135a is removed, thereby completing the via hole 135, that is, completing the intermetallic dielectric layer pattern 130 having the interconnection line region.

Here, shapes of the via hole 135 and the trench 136 are not restricted to those shown in FIG. 2B and may have rounded corners or may be elongated longitudinally or laterally according to the etching method.

In an embodiment of the present invention, it has shown by way of example that the preliminary via hole 135a is first formed and the trench 136 passing over the preliminary via hole 135a is then formed. As long as the preliminary via hole 135a and the trench 136 are formed by general formation techniques, various modifications may be made without departing from the scope of the present invention. For example, the trench may first be formed and the preliminary via hole may then be formed. Alternatively, after forming an intermetallic dielectric layer pattern, a preliminary via hole is filled with a conductive material to form a via, and after forming a trench, the trench may be filled with a conductive material to form an interconnection layer.

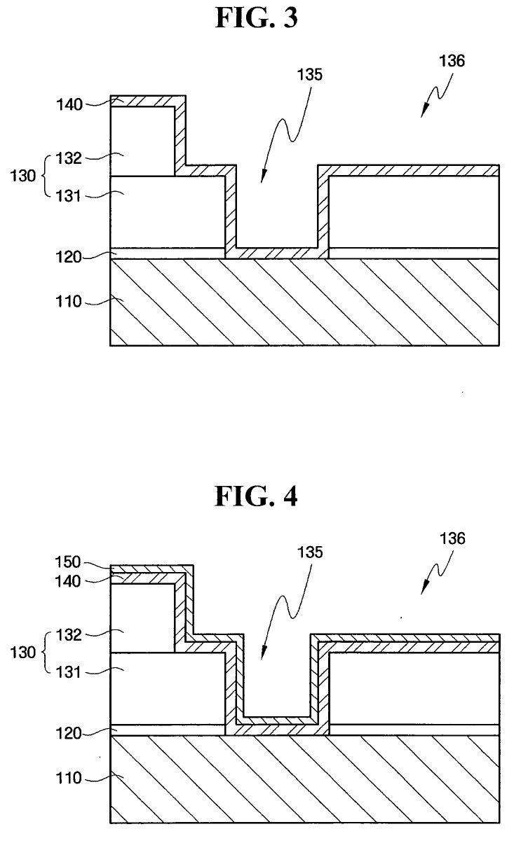

Referring to FIGS. 1 and 3, a diffusion barrier layer 140 is formed on the IMD layer pattern 130 in step S20.

The diffusion barrier layer 140 prevents diffusion of a dual damascene interconnection line to be formed to fill the via hole 135 and the trench 136. This is because Cu used as the dual damascene interconnection layer has a high diffusion coefficient with respect to an IC material such as Si or SiO₂. If Cu diffuses into an insulating layer such as an SiO₂ layer, the insulating layer will have conductivity so that it has a poor insulating property.

The diffusion barrier layer 140 may be formed of a material that does not react with copper or copper alloy or a high fusion point metal, and examples thereof include Ti, Ta, W, Ru, TiN, TaN, WN, TiZrN, TiSiN, TaAlN, TaSiN, TaSi2, TiW and combinations thereof, and stacked layers of these layers. The diffusion barrier layer 140 may be formed to a thickness of 10 to 1000 Å using typically PVD, ALD, CVD, or the like.

Referring to FIGS. 1 and 4, a first adhesion layer 150 is formed on the diffusion barrier layer 140 in step S30.

The first adhesion layer 150 is used to improve adhesion of the diffusion barrier layer 140 with the dual damascene interconnection line to be formed to fill the via hole 135 and the trench 136. In addition, an electro-migration (EM) or stress-induced void (SIV) characteristic can be improved using the first adhesion layer 150.

The first adhesion layer 150 is formed of a material capable of reacting with copper through a predetermined heat treatment process, for example, Ti, Zr, Hf, Sn, La, alloys thereof, and so on. In an embodiment of the present invention, Ti is used. The first adhesion layer 150 is preferably formed to a thickness of 10 to 500 Å, and the shorter, the more preferable. This is because of interdiffusion of an adhesive material forming the first adhesion layer 150, increasing resistivity. The first adhesion layer 150 may be formed using PVD, ALD, CVD, or the like.

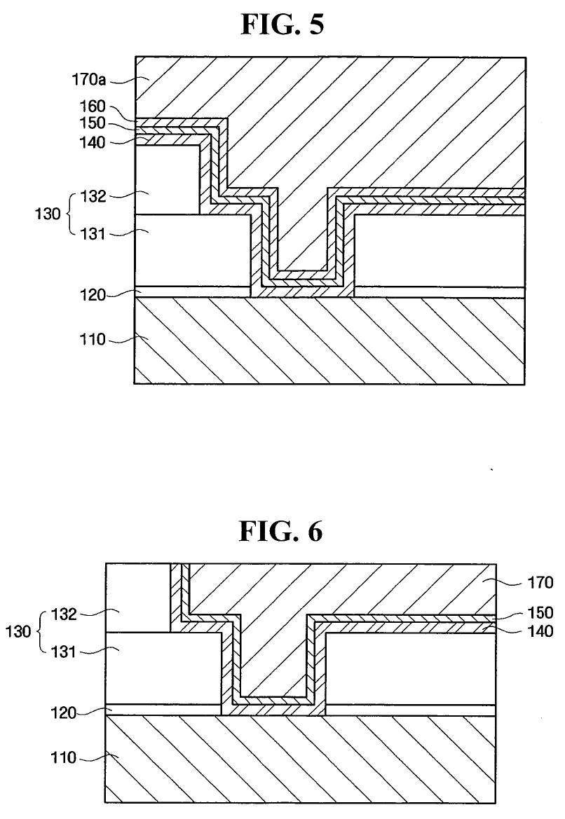

Referring to FIGS. 1 and 5, a seed layer 160 is formed on the first adhesion layer 150 in step S40.

The seed layer 160 may be formed to a thickness of 100-1000 Å by depositing Cu using physical vapor deposition (PVD).

Next, a conductive layer 170a is formed on the seed layer 160 to fill the IMD layer pattern 130. The conductive layer 170a is formed to a thickness sufficient to fill the IMD layer pattern 130 and may be formed using a method having a good filling characteristic such as electroplating, electroless plating, metal organic chemical vapor deposition (MOCVD), or the like.

Referring to FIGS. 1 and 6, a first annealing process is performed in step S50.

The first annealing process may be performed at a temperature below 300° C. A first annealing time varies with a thermal process environment (e.g., temperature or pressure) and, for example, may be in a range of 5 minutes-10 hours. Through the first annealing process, the seed layer 160 and the conductive layer (see 170a of FIG. 5) are integrated and the grains of the conductive layer 170a grow. Once the grains of the conductive layer 170a grow, the resistivity of the conductive layer 170a decreases, for example, from about 2.5 μΩ·cm to about 2.0 μΩ·cm, thereby reducing an RC time delay. Moreover, the hardness of the conductive layer 170a is reduced, facilitating a subsequent planarizing process.

In the first annealing process, the first adhesion layer 150 and the conductive layer 170a may not react with each other. For example, when Ti is used as the first adhesion layer 150, it reacts with Cu at about 300° C. or higher, the first annealing process is preferably performed below 300° C.

The first annealing process may be a self annealing process. That is to say, the grains of the conductive layer 170a can be grown by letting the resulting structure to sit at room temperature for about 2 to about 3 days.

Since the seed layer 160 is incorporated into the conductive layer 170a, it is not shown for convenience of description.

Next, the conductive layer 170a, the first adhesion layer 150, and the diffusion barrier layer 140 are planarized to expose the top surface of the IMD layer pattern 130 in step S60. The resulting structure is a dual damascene interconnection line 170.

To form a planar surface, portions of the conductive layer 170a, the first adhesion layer 150, and the diffusion barrier layer 140 may be non-selectively removed. Preferably, the planar surface is formed by CMP, using a non-selective slurry composition. Here, the non-selective slurry composition contains a silica abrasive material, which removes the different metal layers at substantially the same rate. Alternatively, the planar surface may be formed by a non-selective plasma etching process.

To form a planar surface by performing a selective planarizing process on the conductive layer 170a, the first adhesion layer 150, and the diffusion barrier layer 140, the following conditions may be used. Chemical mechanical polishing (CMP) may be performed on the conductive layer 170a using a neutral slurry including a silica abrasive of about 5 wt % and hydrogen peroxide (H₂O₂) as an oxidizer at a polishing rotation speed (the relative velocity of a polishing pad with respect to the surface of a semiconductor substrate) of 1000 mm/sec and a pressure (applied by the polishing pad to the semiconductor substrate) of about 17 KPa. CMP may be performed on the first adhesion layer 150 and the diffusion barrier layer 140 using a neutral slurry including a silica abrasive of about 5 wt % and hydrogen peroxide (H₂O₂) as an oxidizer at a polishing rotation speed of 760 mm/sec and a pressure of about 14 KPa. Here, the silica abrasives used for the conductive layer 170a and for the first adhesion layer 150 and the diffusion barrier layer 140 may be different from each other.

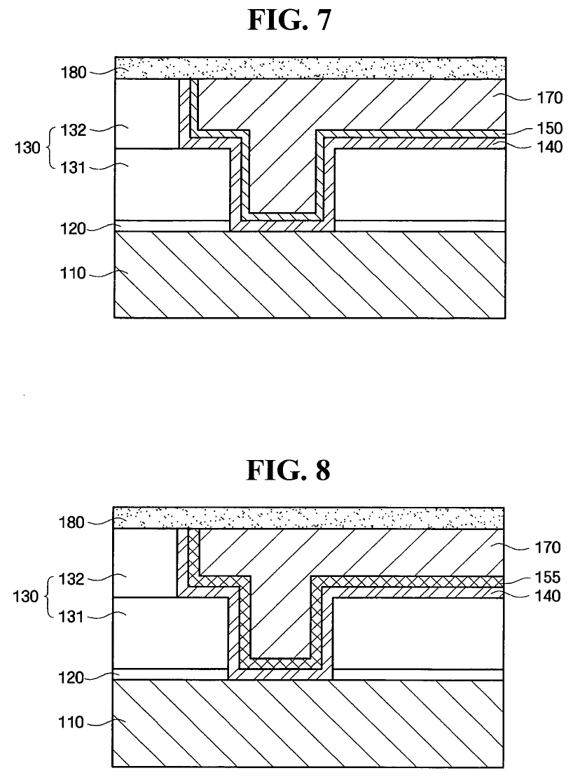

Referring to FIGS. 1 and 7, a capping layer 180 is formed on the dual damascene interconnection line 170 in step S70.

Since a top surface of the dual damascene interconnection line 170 is exposed, a copper oxide layer may be formed. More likely, a copper oxide layer may be formed in a second annealing process. Thus, the capping layer 180 is formed to protect the dual damascene interconnection line 170. The capping layer 180 is typically formed of TiN using CVD to a thickness of 1000 Å.

Particularly, since the capping layer 180 may be formed at a high temperature of about 400° C., an adhesive material of the first adhesion layer 150 may diffuse into the dual damascene interconnection line 170. Moreover, an interface layer 155 to be described below may be formed at an interface between the first adhesion layer 150 and the conductive layer 170a.

Referring to FIGS. 1 and 8, a second annealing process is performed in step S80.

Through the second annealing process, the first adhesion layer 150 and the conductive layer 170a react with each other, thereby forming the interface layer 155. In a preferred embodiment, when Ti is used as the first adhesion layer 150, a Ti—Cu interface layer 155 may be formed. When a rapid thermal process (RTP) is employed as the second annealing process, it is performed at a temperature in a range of about 500 to about 600° C. An annealing time may vary according to annealing conditions and about 20 seconds of the annealing time is necessary under the above-described annealing conditions to form the Ti—Cu interface layer 155. In a case of using a general furnace process during the second annealing process, the annealing conditions include about 300 to about 500° C. in temperature and about 1 hour in process cycle.

The RTP can easily control various annealing parameters, e.g., temperature, pressures, and so on, thereby achieving excellent annealing effects compared to the furnace process. According to the RTP, it is difficult to maintain the temperature at the same level whenever semiconductor substrates are replaced. On the other hand, according to the furnace process, since the internal process chamber is maintained at a thermal equilibrium, the same temperature-to-time characteristic can be easily maintained even with repeated replacement of semiconductor substrates. Thus, the second annealing process can be selectively employed in consideration of the advantages and disadvantages.

In such a manner, the first adhesion layer 150 and the dual damascene interconnection line 170 react with each other by the second annealing process, thereby forming the interface layer 155. Cu has poor adhesion to a material of the diffusion barrier layer 140, e.g., TiN. In an embodiment of the present invention, the interface layer 155 improves adhesion between the dual damascene interconnection line 170 and the diffusion barrier layer 140. Thus, reliability of an EM or SIV characteristic can be improved using the interface layer 155.

In addition, the adhesive material diffused into the dual damascene interconnection line 170, i.e., Ti, out-diffuses to the interface layer 155. That is, since a concentration of the adhesive material in the dual damascene interconnection line 170 is reduced, the resistivity of the dual damascene interconnection line 170 decreases, which results in exhaustion of Ti diffused into the dual damascene interconnection line 170, apparently making Cu—Ti bonds in the interface layer 155 into a Ti-rich compound.

In a case where the interconnection line is comprised of a stack of multiple layers, the second annealing process may be performed just once. Since the second annealing process is performed after forming the capping layer 180, it is not necessary to perform the second annealing process for every interconnection line. That is, after all interconnection lines are stacked, the second annealing process is performed once at the last stage, so that a thermal budget is reduced, thereby advantageously decreasing SIV failures and processing numbers.

As shown in FIG. 8, an interconnection line of a semiconductor device according to an embodiment of the present invention includes the lower interconnection line 110, the barrier insulating film 120, the IMD layer pattern 130, the diffusion barrier layer 140, the interface layer 155, the dual damascene interconnection line 170, and the capping layer 180.

While the above-described damascene interconnection line of the semiconductor device according to an embodiment of the present invention is constructed such that it is connected to only the lower interconnection line 110, the invention is not limited to this. That is, the damascene interconnection line of the semiconductor device according to an embodiment of the present invention can also be connected to a source and/or a drain of a transistor through a contact plug. In this case, a counterpart of the intermetal insulating film 130 corresponds to an interlayer dielectric pattern.

The barrier insulating film 120 prevents diffusion of Cu of the lower interconnection line 110 and/or the dual damascene interconnection line 170 and serves as an etching stopper. The barrier insulating film 120 may be formed of SiN, SiC, SiON, or SiCN to a thickness of 200-1000 Å.

The IMD layer pattern 130 includes the region for forming an interconnection line such as a via hole or a trench to form the dual damascene interconnection line 170.

The IMD layer pattern 130 is preferably made of a low-k material.

The diffusion barrier layer 140 prevents diffusion of Cu of the dual damascene interconnection line 170. The diffusion barrier layer 140 may be formed of a material that does not react with copper or copper alloy or a high fusion point, metal to a thickness of 10 to 1000 Å.

The interface layer 155 improves adhesion between the dual damascene interconnection line 170 and the barrier insulating film 120. In particular, in an embodiment of the present invention the adhesive material of the first adhesion layer 150 used to form the interface layer 155 scarcely diffuses into the dual damascene interconnection line 170. Thus, the resistivity of the dual damascene interconnection line 170 hardly changes. It is known in the art that even a slight amount, i.e., about 1%, of a material forming the first adhesion layer 150, e.g., Ti, diffused into a Cu interconnection drastically increases resistivity of the dual damascene interconnection line 170, i.e., greater than 10 times.

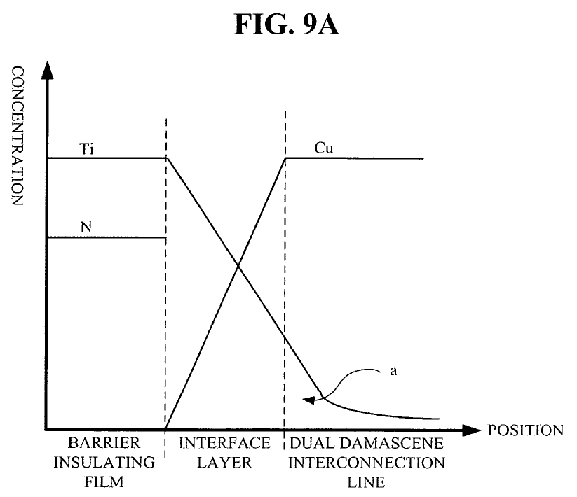

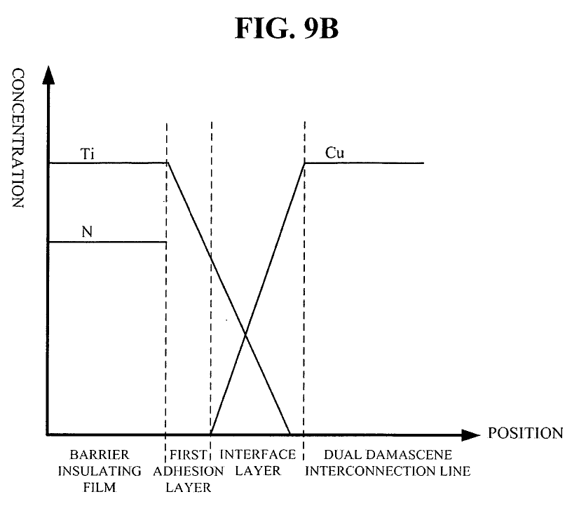

FIGS. 9A and 9B show changes in the concentration depending on positions relative to interconnection lines of a conventional semiconductor device and a semiconductor device according to an embodiment of the present invention, respectively.

According to the conventional technology, growth of crystal grains and formation of an interface layer are simultaneously performed by a single annealing process, unlike in the present invention. As shown in FIG. 9A, the adhesive material Ti is diffused widely so that the interface layer is formed thickly. In addition, Ti is diffused up to a dual damascene interconnection area (see “a” area).

By contrast, referring to FIG. 9B, in an embodiment of the present invention, a low-temperature, first annealing process and a high-temperature, second annealing process are performed, that is to say, growth of copper crystal grains and formation of an interface layer are separately performed. That is, as shown in FIG. 9B, since the adhesive material Ti is not diffused widely, the interface layer is formed narrowly. In addition, although the results may differ depending on the thickness and the second annealing process conditions, the first adhesion layer may react completely without forming the interface layer but some of the first adhesion layer made of Ti may remain.

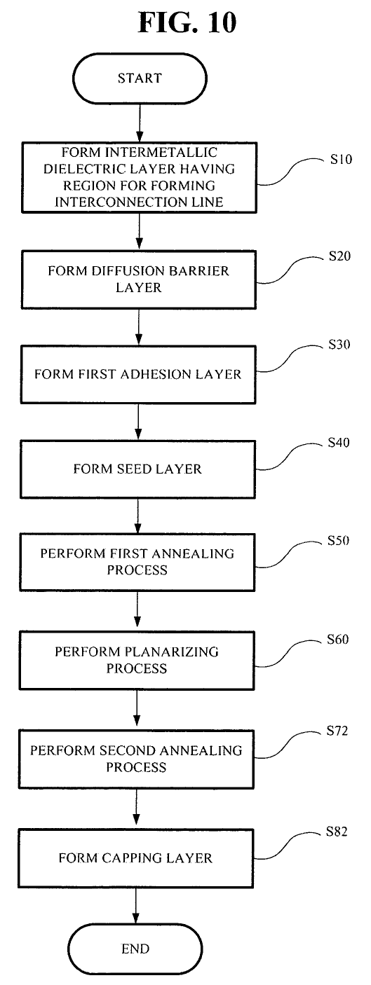

FIG. 10 is a flowchart illustrating a method for fabricating an interconnection line in a semiconductor device according to another embodiment of the present invention. Substantially the same functional components as those shown in FIG. 1 are identified by the same reference numerals, and their repetitive description will be omitted.

Referring to FIG. 10, the method for fabricating an interconnection line of a semiconductor device according to another embodiment of the present invention is different from the interconnection line fabricating method shown in FIG. 1 in that a second annealing process is performed prior to forming of a capping layer (see steps S72 and S82). Here, in such a case where multiple interconnection layers are stacked, after the depositing of the plurality of interconnection line layers, the second annealing process is then performed on each interconnection line, increasing a thermal budget.

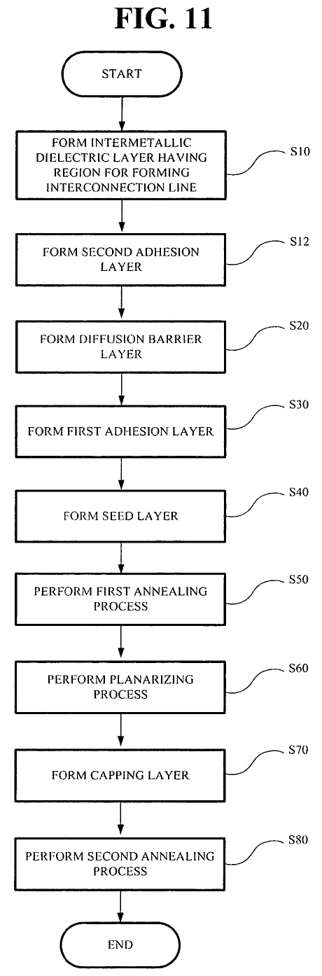

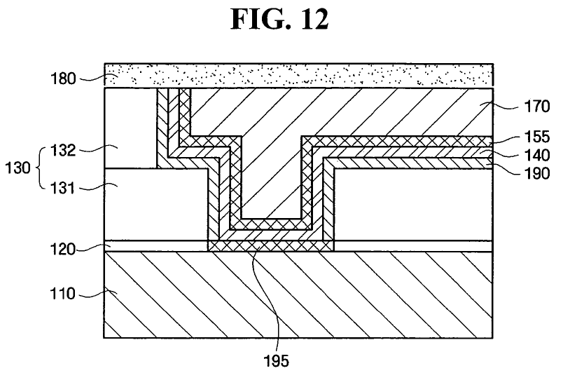

FIG. 11 is a flowchart illustrating a method for fabricating an interconnection line in a semiconductor device according to still another embodiment of the present invention, and FIG. 12 is a sectional view illustrating an interconnection line of a semiconductor device according to another embodiment of the present invention. Substantially the same functional components as those shown in FIG. 1 are identified by the same reference numerals, and their repetitive description will be omitted.

Referring to FIGS. 11 and 12, the method for fabricating the interconnection line of a semiconductor device according to still another embodiment of the present invention is different from the interconnection line fabricating method shown in FIG. 1 in that a second adhesion layer 190 is further formed prior to the formation of the diffusion barrier layer 140 (see step S12).

When the lower interconnection line layer 110 is formed of Cu, the second adhesion layer 190 is formed to improve adhesion between the lower interconnection line layer 110 and the diffusion barrier layer 140. As when using the first adhesion layer 150, reliability of an EM or SIV characteristic can be improved using the second adhesion layer 190.

The second adhesion layer 190 is formed of a material capable of reacting with Cu during a thermal process, such as Ti, Zr, Hf, Sn, La, or alloys thereof. In the current embodiment of the present invention, Ti is used. The second adhesion layer 190 may be formed to a thickness of 10 to 500 Å, and the thinner, the more preferable. The second adhesion layer 190 may be formed using PVD, ALD, CVD, or the like.

The second adhesion layer 190 reacts with the lower interconnection line layer 110 during a second annealing process (step S80), thereby forming an interface layer 195 as shown in FIG. 12. Here, the interface layer cannot be formed at an interface between the second adhesion layer 190 and the IMD layer pattern 130.

Thus, according to still another embodiment of the present invention, adhesion between the lower interconnection line layer 110 and the diffusion barrier layer 140 can be improved using the second adhesion layer 190.

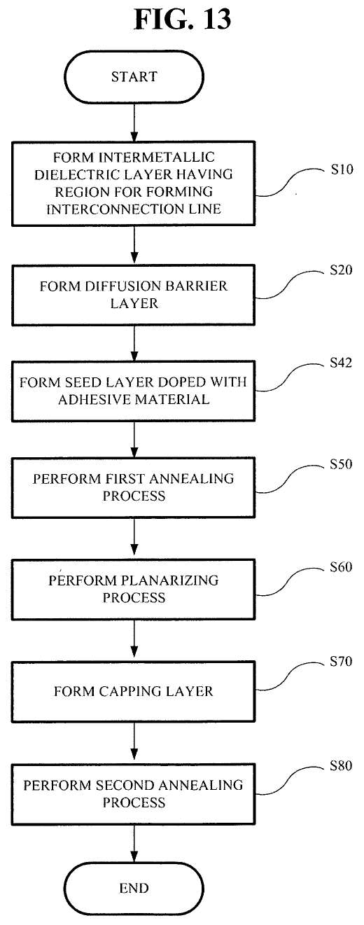

FIG. 13 is a flowchart illustrating a method for fabricating an interconnection line in a semiconductor device according to yet another embodiment of the present invention. Substantially the same functional components as those shown in FIG. 1 are identified by the same reference numerals, and their repetitive description will be omitted.

According to yet another embodiment of the present invention, a first adhesion layer and a seed layer are not separately formed. That is, a seed layer having an adhesive material and a conductive material mixed together is used without separately forming a first adhesion layer.

Here, the seed layer having the adhesive material and the conductive material mixed together may be formed to a thickness of 10 to 1000 Å. Here, the adhesive material is preferably contained in the seed layer in an amount of not greater than 10% based on the total weight of the seed layer. If the proportion of the adhesive material relative to the seed layer overly increases, the adhesive material may be likely to diffuse into the dual damascene interconnection, ultimately increasing resistivity of the damascene interconnection. Like the material forming the first adhesion layer, the material forming the adhesion layer may be Ti, Zr, Hf, Sn, La, or alloys thereof.

The present invention will be described in detail through the following concrete experimental examples. However, the experimental examples are for illustrative purposes and other examples and applications can be readily envisioned by a person of ordinary skill in the art. Since a person skilled in the art can sufficiently analogize the technical contents which are not described in the following concrete experimental examples, the description thereof is omitted.

### EXPERIMENT EXAMPLE 1

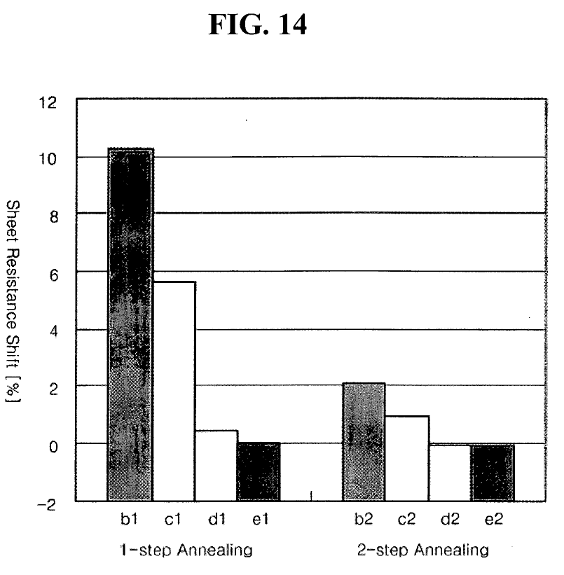

In FIG. 14, b1 indicates a case in which TiZrN is used as a diffusion barrier layer formed to a thickness of 150 Å and TiZr is used as a first adhesion layer formed to a thickness of 150 Å. In FIG. 14, c1 indicates a case in which TiZr is used as a second adhesion layer formed to a thickness of 75 Å and TiZrN is used as a diffusion barrier layer to a thickness of 150 Å, and TrZr was used as a first adhesion layer to a thickness of 75 Å. In FIG. 14, d1 indicates a case in which TiZrN was used as only a diffusion barrier layer to a thickness of 300 Å. In FIG. 14, e1 indicates a case in which Ta/TaN was used as a diffusion barrier layer to a thickness of 150 Å.

In b1 through e1, the grain growth of Cu and the formation of an interface layer were simultaneously performed by one-step annealing like in the prior art. In b2 through e2, the same materials as those used in b1 through e1 were formed to the same thicknesses, but the growth of Cu grains and the formation of the interface layer were separately performed by two-step annealing process according to the present invention.

Next, sheet resistance variations of the Cu interconnection line in b1 through e1 and b2 through e2 were measured and the result thereof is shown in FIG. 14. Although multiple experiment examples were made based on b1 through e1 and b2 through e2, medians are just shown in FIG. 14.

In the prior art, that is, in d1 and e1, the first adhesion layer and the second adhesion layer were not formed. Thus, little increase in the sheet resistance of the Cu interconnection line was exhibited. An about 10% increase in the sheet resistance was exhibited in b1 while an about 5% in the sheet resistance was exhibited in c1.

On the other hand, in the present invention, that is, in d2 and e2, the first adhesion layer and the second adhesion layer were not formed. Thus, little increase in the sheet resistance of the Cu interconnection line was exhibited. About a 2% increase in the sheet resistance was exhibited in b2 while about 1% increase in the sheet resistance was exhibited in c2. Therefore, according to the present invention, compared to the prior art, an increase in the sheet resistance of the Cu interconnection is considerably lowered.

### EXPERIMENT EXAMPLE 2

In f1, a diffusion barrier layer is formed of TiN to a thickness of 150 Å and a first adhesion layer is formed of Ti to a thickness of 150 Å. In g1, only a diffusion barrier layer is formed of TiN to a thickness of 300 Å.

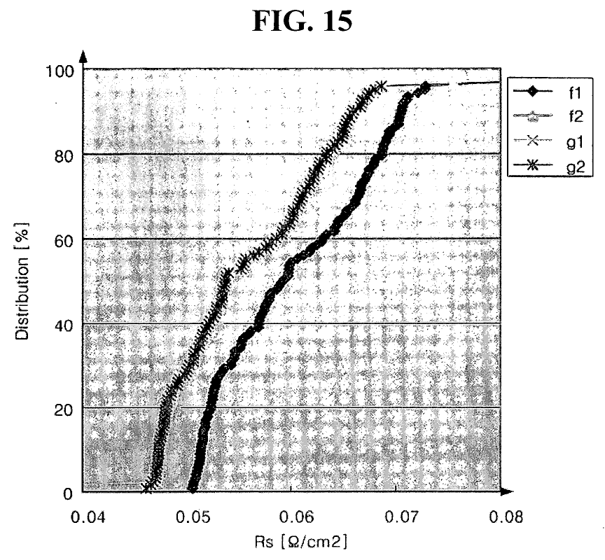

Referring to FIG. 15, In f1 and g1, the grain growth of Cu and the formation of an interface layer are simultaneously performed by one-step annealing like in the prior art. In f2 through g2, the same materials are formed to the same thicknesses as in f1 through g1, but the grain growth of Cu and the formation of an interface layer are separately performed through a two-step annealing process like in the present invention.

Next, the sheet resistance distribution of a Cu interconnection line with respect to f1 through g1 and f2 through g2 are measured and the result thereof is shown in FIG. 15.

It can be seen that the sheet resistance distributions of a Cu interconnection line in g1 and g2 where a first adhesion layer is not used are similar to each other. On the other hand, the sheet resistance distributions of a Cu interconnection line in f1 and f2 where the first adhesion layer is used are greatly different from each other by the number of times of annealing. That is, the sheet resistance distribution of a Cu interconnection line in f2 where annealing is performed twice has a difference of about 0.005 Ω/cm² with the sheet resistance distribution of a Cu interconnection line in f1 where annealing is performed once.

As described above, the method for fabricating interconnection line in a semiconductor device of the present invention according to the present invention provides at least one of the following advantages.

First, resistivity of a Cu interconnection line can be improved by forming an interface layer through a two-step annealing process.

Second, reliability of the Cu interconnection line such as an electro-migration (EM) or stress-induced void (SIV) characteristic can be improved.

Third, since a second annealing process is performed after the formation of a capping layer, an oxidized copper layer is not formed on a planar conductive layer. In addition, even when a plurality of interconnection line layers is formed, since the second annealing process is performed at the last step, the second annealing process is performed just once. Therefore, a thermal budget is reduced and numbers of SIV failures and processes are reduced.

Fourth, it is not necessary to additionally deposit a first adhesion layer using a seed layer having an adhesive material and a conductive material mixed together, thereby reducing the number of processes.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method for fabricating an interconnection line in a semiconductor device, the method comprising:
forming on a semiconductor substrate a dielectric layer pattern including a region for forming the interconnection line;
forming a diffusion barrier layer on the dielectric layer pattern;
forming a first adhesion layer on the diffusion barrier layer;
forming a seed layer on the first adhesion layer;
forming a conductive layer to fill the region for forming the interconnection line;
performing grain growth of the conductive layer by performing a first annealing process;
planarizing the conductive layer to expose the top surface of the dielectric layer pattern; and
forming an interface layer through reaction between the first adhesion layer and the conductive layer by performing a second annealing process at a temperature higher than that of the first annealing process.

2. The method of claim 1, wherein the first annealing process is performed at a temperature where the first adhesion layer and the conductive layer do not react with each other.

3. The method of claim 2, wherein the first annealing process is performed at a temperature of 300° C. or lower

4. The method of claim 1, wherein the second annealing process is performed at a temperature in a range of 300-600° C.

5. The method of claim 1, wherein the first adhesion layer is formed to a thickness in a range of 10-500 Å.

6. The method of claim 1, wherein the first adhesion layer comprises at least one of Ti, Zr, Hf, Sn, La, and an alloy thereof.

7. The method of claim 1, wherein the conductive layer is formed of at least one of Cu and an alloy thereof.

8. The method of claim 1, further comprising, before forming the interface layer, forming on the planar conductive layer a capping layer that protects the planar conductive layer.

9. The method of claim 1, further comprising, after forming the interface layer, forming on the planar conductive layer a capping layer that protects the planar conductive layer.

10. The method of claim 1, further comprising forming a second adhesion layer on the dielectric layer pattern before forming the diffusion barrier layer.

11. A method for fabricating an interconnection line in a semiconductor device, the method comprising:
forming on a semiconductor substrate a dielectric layer pattern including a region for forming the interconnection line;
forming a diffusion barrier layer on the dielectric layer pattern;
forming a seed layer where an adhesive material and a conductive material are combined on the diffusion barrier layer;
forming a conductive layer to fill the region for forming the interconnection line;
performing grain growth of the conductive layer by performing a first annealing process;
planarizing the conductive layer to expose the top surface of the dielectric layer pattern; and
forming an interface layer through reaction between the diffusion barrier layer and the conductive layer by performing a second annealing process at a temperature higher than that of the first annealing process.

12. The method of claim 11, wherein the first annealing process is performed at a temperature of 300° C. or lower

13. The method of claim 11, wherein the second annealing process is performed at a temperature in a range of 300-600° C.

14. The method of claim 11, wherein the seed layer is formed to a thickness in a range of 10-500 Å.

15. The method of claim 11, wherein the seed layer contains an adhesive material in an amount not greater than 10% based on the total weight of the mixture.

16. The method of claim 11, wherein the adhesive material is formed of a material selected from the group consisting of Ti, Zr, Hf, Sn, La, and an alloy thereof.

17. The method of claim 11, wherein the conductive layer comprises at least one of Cu and an alloy thereof.

18. The method of claim 11, further comprising, before forming the interface layer, forming on the planar conductive layer a capping layer that protects the planar conductive layer.

19. The method of claim 11, further comprising, after forming the interface layer, forming on the planar conductive layer a capping layer that protects the planar conductive layer.

20. The method of claim 11, further comprising forming an adhesion layer on the dielectric layer pattern before forming the diffusion barrier layer.
